(19) United States
(12) Patent Application Publication
(10) Pub. No.: US 2023/0422467 A1
(43) Pub. Date: Dec. 28, 2023

(54) TRANSISTOR, FABRICATION METHOD, AND MEMORY

(71) Applicants: CHANGXIN MEMORY TECHNOLOGIES, INC., Hefei City (CN); BEIJING SUPERSTRING ACADEMY OF MEMORY TECHNOLOGY, Beijing (CN)

(72) Inventors: Deyuan XIAO, Hefei City (CN); Yong Yu, Hefei City (CN); Guangsu Shao, Hefei City (CN)

(21) Appl. No.: 17/934,647

(22) Filed: Sep. 23, 2022

(30) Foreign Application Priority Data
Jun. 28, 2022 (CN) 202210755199.3

(51) Int. Cl. H01L 27/108

(52) U.S. Cl. CPC H01L 27/10873; H01L 27/10814

(57) ABSTRACT

The present disclosure is applicable to the field of semiconductors, and provides a transistor, a fabrication method, and a memory. The transistor includes: a semiconductor substrate, silicon support pillars, located on the semiconductor substrate, and gates, each of the gates arranged around one of the silicon support pillars. A side surface of each of the gates close to the silicon support pillar is a first surface, a side surface of each of the gates distant from the silicon support pillar is a second surface, and the length of the first surface is less than the length of the second surface. The length of the first surface of each of the gates is less than the length of the channel region of each of the silicon support pillars.

### CROSS-REFERENCE TO RELATED APPLICATION

This application claims the priority of Chinese Patent Application No. 202210755199.3, submitted to the Chinese Intellectual Property Office on Jun. 28, 2022, the disclosure of which is incorporated herein in its entirety by reference.

### TECHNICAL FIELD

The present disclosure relates to the field of semiconductors, and in particular, to a transistor, a fabrication method, and a memory.

### BACKGROUND

Semiconductors are used in integrated circuits, consumer electronics, communication systems, photovoltaic power generation, lighting, high-power power conversion and other fields. For example, diodes are devices made of the semiconductors. A transistor is a semiconductor device used as an amplifier or electric control switch, and is a basic building block in most electronic products, such as computers, mobile phones, or digital recorders.

The structural feature of a gate-around transistor itself is that: a channel of the gate-around transistor is completely surrounded by a gate. Such a structural feature greatly enhances the gate control capability of the gate-around transistor, and also effectively suppresses the problems that the off-state leakage current (I_{off}) of the device caused by the short-channel effect in ordinary metal-oxide-semiconductor field effect transistors (MOSFETs) increases sharply with the decrease of the channel length, the threshold voltage decreases significantly with the decrease of the channel length, etc. On the contrary, precisely because of such a structural feature, two leakage mechanisms, namely a gate-induced drain leakage (GIDL) effect and gate direct tunneling are aggravated, resulting in undesired static leakage. The GIDL effect includes two physical mechanisms of tunneling: transverse band-to-band tunneling (T-BTBT) and longitudinal band-to-band tunneling (L-BTBT). T-BTBT occurs in a region where a drain and the gate overlap, and L-BTBT occurs in a region where the drain and the channel overlap.

With the development of the semiconductor industry, the scaling of device sizes has become the focus of modern electronic device research. For a nanoscale gate-all-around device, a leakage current has a decisive impact on the power consumption, lifespan and performance of the device. Therefore, how to reduce power consumption of a gate-around device caused by the static leakage has become an unavoidable problem in device design and even circuit design.

### SUMMARY

In a first aspect, the present disclosure provides a transistor, including:
a semiconductor substrate; silicon support pillars, located on the semiconductor substrate, and gates, each of the gates arranged around one of the silicon support pillars; where,
a side surface of each of the gates close to the silicon support pillar is a first surface, a side surface of each of the gates distant from the silicon support pillar is a second surface, and a length of the first surface is less than a length of the second surface; and the length of the first surface of each of the gates is less than a length of a channel region of each of the silicon support pillars.

In a second aspect, the present disclosure also provides a method of fabricating a transistor, including:
performing ion doping on silicon support pillars on a semiconductor substrate; and forming a channel region, a source region, and a drain region on each of the silicon support pillars after the doping; and
depositing a gate at a periphery of each of the channel regions; where, a side surface of each of the gates close to the silicon support pillar is a first surface, a side surface of each of the gates distant from the silicon support pillar is a second surface, and a length of the first surface is less than a length of the second surface; and the length of the first surface of each of the gates is less than a length of the channel region of each of the silicon support pillars.

In another aspect, the present disclosure also provides a memory, including the transistor described above.

Other features and advantages of the present disclosure will be illustrated in the following description, and some of these will become apparent from the description or be understood by implementing the present disclosure. The objectives and other advantages of the present disclosure may be achieved and derived from the structures indicated in the description and accompanying drawings.

### BRIEF DESCRIPTION OF THE DRAWINGS

To describe the technical solutions in the embodiments of the present disclosure or in the prior art more clearly, the following briefly describes the drawings required for describing the embodiments or the prior art. Apparently, the drawings in the following description show some embodiments of the present disclosure, and those of ordinary skill in the art may still derive other drawings from these drawings without creative efforts.

FIG. 1 is a schematic diagram of a transistor according to one embodiment of the present disclosure;

FIG. 2 is an enlarged view of a position A in FIG. 1;

FIG. 3 is a flowchart of fabrication of a transistor according to one embodiment of the present disclosure;

FIG. 4 is a schematic structural diagram of silicon support pillars of a transistor in an initial state according to one embodiment of the present disclosure;

FIG. 5 is a schematic structural diagram of silicon support pillars of a transistor after rounding processing according to one embodiment of the present disclosure;

FIG. 6 is a schematic structural diagram of silicon support pillars of a transistor during ion doping processing according to one embodiment of the present disclosure;

FIG. 7 is a schematic structural diagram of a transistor after deposition of dielectric rings according to one embodiment of the present disclosure;

FIG. 8 is a schematic structural diagram of a transistor after deposition of second oxide layers according to one embodiment of the present disclosure;

FIG. 9 is a schematic structural diagram of a transistor after deposition of second dielectric rings according to one embodiment of the present disclosure;

FIG. 10 is a schematic structural diagram of a transistor after etching of third oxide layers according to one embodiment of the present disclosure;

FIG. 11 is a schematic structural diagram of a transistor after deposition of gate oxide layer according to one embodiment of the present disclosure;

FIG. 12 is a schematic structural diagram of a transistor after deposition of gates according to one embodiment of the present disclosure;

FIG. 13 is a schematic structural diagram of a transistor after deposition of passivation layer according to one embodiment of the present disclosure;

FIG. 14 is a schematic structural diagram of a transistor after etching of shallow-trench channels according to one embodiment of the present disclosure;

FIG. 15 is a chart of changing trend of a fence parasitic capacitance with a gate voltage according to one embodiment of the present disclosure;

FIG. 16 is a chart of changing trend of an on-off ratio with thicknesses of dielectric rings according to one embodiment of the present disclosure;

FIG. 17 is a chart of changing trend of an off-state current with thicknesses of dielectric rings according to one embodiment of the present disclosure;

FIG. 18 is a chart of changing trend of an on-state current with thicknesses of dielectric rings according to one embodiment of the present disclosure;

FIG. 19 is a chart of changing trend of an off-state ratio with lengths of dielectric rings according to one embodiment of the present disclosure; and

FIG. 20 is a chart of changing trend of an on-state current with lengths of dielectric rings according to one embodiment of the present disclosure.

### DETAILED DESCRIPTION

To make the objectives, technical solutions, and advantages of the embodiments of the present disclosure clearer, the following clearly and completely describes the technical solutions in the embodiments of the present disclosure with reference to the accompanying drawings in the embodiments of the present disclosure. Apparently, the described embodiments are some but not all of the embodiments of the present disclosure. All other embodiments obtained by those of ordinary skill in the art based on the embodiments of the present disclosure without creative efforts should fall within the protection scope of the present disclosure.

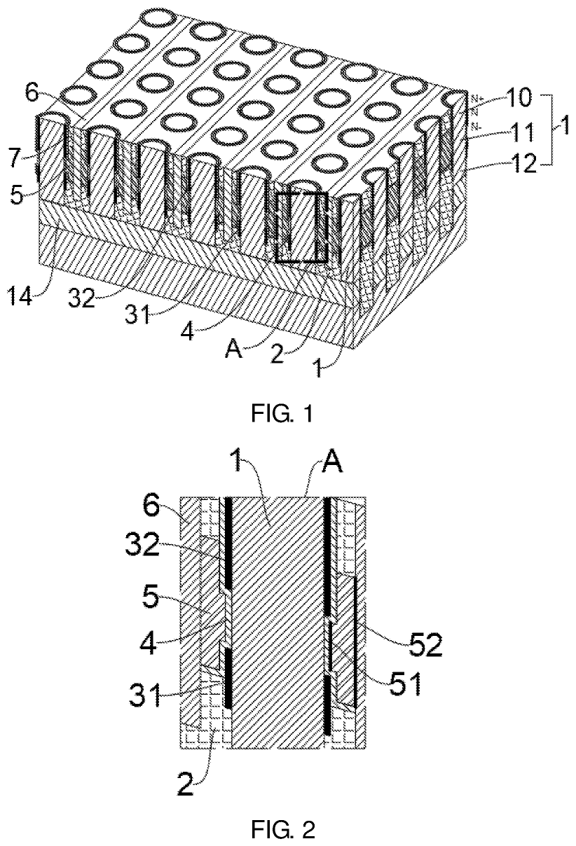

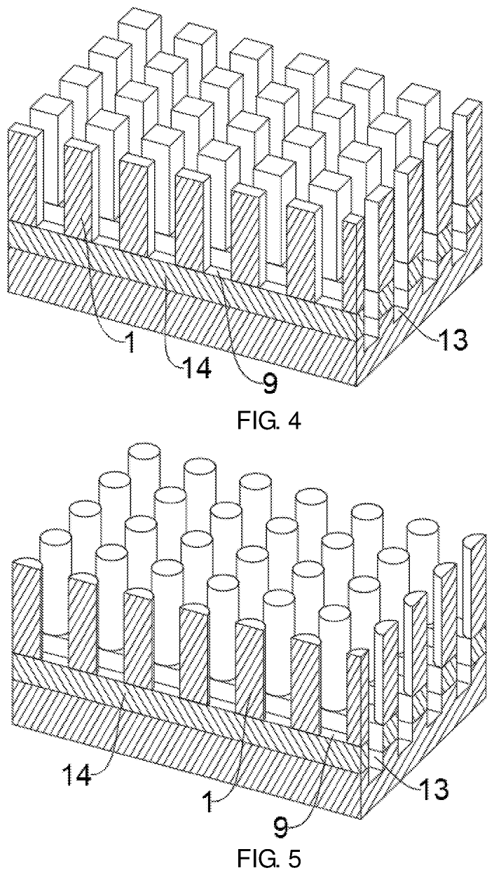

FIG. 1 is a schematic diagram of a transistor according to one embodiment of the present disclosure. The transistor includes: a semiconductor substrate, silicon support pillars 1, located on the semiconductor substrate, and gates 5, each of the gates 5 arranged around one of the silicon support pillars 1. A side surface of each of the gates 5 close to the silicon support pillar 1 is a first surface 51, and a side surface of each of the gates 5 distant from the silicon support pillar 1 is a second surface 52, as shown in FIG. 2. The length of the first surface 51 of each of the gates 5 is less than a length of a channel region 11 of each of the silicon support pillars. The length of the channel region 11 formed through a Gaussian doping concentration can be controlled when ion doping is performed. In addition, when a gate metal layer is deposited, the thicknesses of the metal layer may be adjusted through deposition and etching, such that the length of the channel region 11 and the length of the first surface 51 of the gate 5 can be controlled, and the length relationship therebetween may be achieved through a fabrication process. In FIG. 1, the semiconductor substrate may be selected from a material suitable for a semiconductor process, and some materials containing silicon may be used as materials for fabricating the semiconductor substrate, such as silicon, single crystal or polycrystalline silicon, amorphous silicon, carbon-doped silicon and combinations thereof, or a multilayer of two or more thereof. The silicon support pillars 1 are uniformly distributed on the semiconductor substrate. In FIG. 1, the arrangement of the plurality of silicon support pillars 1 on the semiconductor substrate is an array arrangement. That is, the silicon support pillars 1 are arranged in an orderly manner along a length direction and width direction of the semiconductor substrate. The distance between adjacent two of the silicon support pillars 1 is equal to form a square or rectangular array. In addition to this arrangement, the distance between adjacent two of the silicon support pillars 1 may not be equal. The above array arrangement maintains the same distance between adjacent two of the silicon support pillars 1 to make the arrangement orderly, which can facilitate the deposition of a plurality of functional layers and the etching of word lines and bit lines. Moreover, in addition to being arranged along the above straight line direction, the silicon support pillars 1 may also be arranged in a manner of a ring-layer annular array or a manner of helical scattering. However, to reduce the cost and time of the subsequent process, the arrangement of the silicon support pillars 1 is preferably in some orderly arrangement compared with the disordered arrangement. The silicon support pillars 1 are subjected to rounding passivation, and round corners of the rectangular silicon support pillars 1 shown in FIG. 4 are passivated to form the cylindrical or elliptical silicon support pillars 1 shown in FIG. 1 or FIG. 5. Rounding the silicon support pillars 1 may further miniaturize the silicon support pillars 1 to solve the problem that in the prior art, the shapes of the silicon support pillars 1 are mostly square, such that the process sizes are relatively large. For the transistor, the size of the transistor itself is very small. On the basis that the silicon support pillars 1 can complete their own required performance, after the silicon support pillars 1 are subjected to rounding passivation processing, the number of silicon support pillars 1 arranged per unit area increases. Oxide layers are formed simultaneously on the semiconductor substrate and the silicon support pillars 1 through a thermal oxidation process; and then, the silicon support pillars 1 are etched. The outer surfaces of the silicon support pillars 1 after the rounding passivation are arc-shaped or smoothly curved, and there are no obvious protruding points on the outer surfaces of the silicon support pillars 1, such that when electrons flow, the accumulation of the electrons at the corners or protrusions may be reduced, the transistor is prevented from being prone to leakage, breakdown or damage at a single point and other failures, and when the metal gates are deposited later, the cylindrical outer surfaces of the silicon support pillars 1 are also easy to form a good fit with the metal gates, and it is not easy to form voids in places having inflection points such as corners or protrusions. Therefore, the silicon support pillars 1 after the rounding passivation can make a better vertical gate-all-around (VGAA) structure, reduce defects, reduce gate leakage, etc., to achieve better performance.

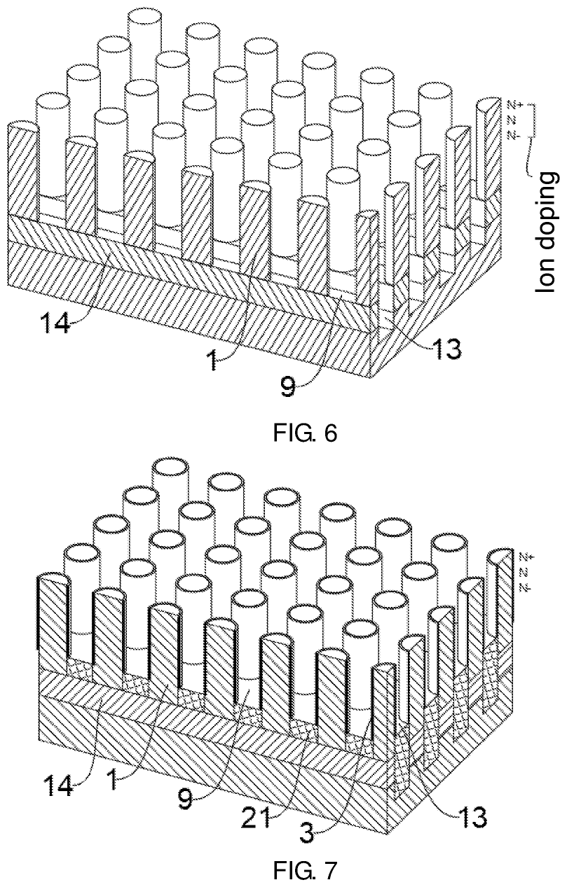

Ion doping is performed on the upper end of each of the silicon support pillars 1 to form the drain region 10, the channel region 11, and the source region 12, the drain region is connected to one end of the channel region 11, and the other end of the channel region 11 is connected to the source region 12. Setting the ion doping concentration gradient to relatively gentle Gaussian doping may effectively reduce the leakage of L-BTBT, thereby reducing I_{off} (off-state leakage current of the device). As shown in FIG. 1 and FIG. 6, N⁺ is a high-concentration ion-doped region, and N⁻ is a low-concentration ion-doped region. In one embodiment, the silicon support pillars 1 is subjected to ion doping multiple times, and the ion doping concentration gradient on the silicon support pillars 1 decreases gradually from top to bottom. Specifically, the silicon support pillars 1 may be subjected to the ion doping more than three times to achieve a relatively gentle concentration gradient.

In one embodiment of the present disclosure, the semiconductor substrate is covered with a first isolation layer 2, second isolation layers 6 are provided on the first isolation layer 2, one end of each of the second isolation layers 6 is inserted into the first isolation layer 2, and each of the second isolation layers 6 is located between two adjacent columns of the silicon support pillars 1. As shown in FIG. 1, an interface of the first isolation layer 2 is U-shaped, one end of each of the second isolation layers 6 is inserted into the U-shaped first isolation layer 2, the second isolation layers 6 are made of deposited oxides to form word line shallow trench isolation (STI), and the first isolation layer 2 and the second isolation layers 6 are all made of insulating materials.

Each of the silicon support pillars 1 is coated with a dielectric ring. Each of the dielectric rings includes a first dielectric ring 31 and a second dielectric ring 32, each of the first dielectric rings 31 is provided with one end inserted into the first isolation layer 2 and the other end close to the gate 5, and each of the second dielectric rings 32 is provided with one end close to the gate 5 and the other end located on a same horizontal plane with a top of the silicon support pillar 1. An insulating dielectric ring is added at the periphery of a channel close to the drain extension region, and may be made of insulating materials such as silicon dioxide, silicon nitride, and hafnium dioxide. The dielectric constant of the dielectric rings is relatively large, and adjusting the threshold voltage and reducing the GIDL effect are mainly due to the coupling effect of a High-k material (hafnium Hf element-based material) on the drain extension regions, resulting in the increase of a fringing electric field of the drain extension regions with the increase of the dielectric constant of sidewalls (i.e., the dielectric rings). This increased fringing electric field at the interfaces between the channels and the drain extension regions is reflected in the energy band change, which reduces the change in a vertical energy band and increases the tunneling width when L-BTBT occurs, thereby reducing the band-to-band tunneling probability of carriers, and reducing the off-state current. As shown in FIG. 1, one end of each of the first dielectric rings 31 is inserted into the U-shaped first isolation layer 2 and attached to the outer wall of the silicon support pillar 1. In addition, each of the second dielectric rings 32 is also attached to the outer wall of the silicon support pillar 1, and extends downwards from the top of the silicon support pillar 1. The first dielectric rings 31 are not connected to the second dielectric rings 32, and are separated from the second dielectric rings 32. A protrusion is provided on one side of each of the gates 5 close to outer surface of the silicon support pillar 1, and the protrusion is located at a separation position between the first dielectric ring 31 and the second dielectric ring 32. The protruding structure of the gate 5 herein is to separate the first dielectric ring 31 from the second dielectric ring 32.

The gates 5 around the plurality of silicon support pillars 1 are connected. The gates 5 are made of metals, and can serve as word lines (WLs) for controlling on and off of transistor cells. A gate oxide layer 4 is provided between the first dielectric ring 31 and the gate 5, between the second dielectric ring 32 and the gate 5, and between the silicon support pillar 1 and the gate 5; and the gate oxide layer 4 is provided with one end fitted with the first isolation layer 2 and the other end flush with the tops of the silicon support pillars 1. As shown in FIG. 1, the gate oxide layer 4 is fitted with outer surfaces of the first dielectric rings 31, outer surfaces of the second dielectric rings 32, and outer surfaces of the silicon support pillars 1 at the separation positions between the first dielectric rings 31 and the second dielectric rings 32; and the bottom of the gate oxide layer 4 separates the gates 5 from the first isolation layer 2.

Based on the above structures, the above structures are tested and analyzed. FIG. is a chart of changing trend of a fence parasitic capacitance (C_{gg}) with a gate voltage (V_{GS}) according to one embodiment of the present disclosure. After channel dielectric rings (i.e., the first dielectric rings 31 and the second dielectric rings 32) are added, the GIDL leakage current of the channel dielectric ring GAAFET is nearly 3 times lower than that of the conventional vacuum sidewall GAAFET, and is more than 1 times lower than that of the conventional SiO₂ sidewall GAAFET. The on-off ratio of the channel dielectric ring GAAFET is almost 4 times that of the conventional vacuum sidewall GAAFET, and nearly twice that of the conventional SiO₂ sidewall GAAFET, which is very suitable for the design implementation of low-power circuits. The fence parasitic capacitance of the channel dielectric ring GAAFET is 13.6% lower than that of the conventional SiO₂ sidewall GAAFET, and 2.8% lower than that of the conventional vacuum sidewall GAAFET.

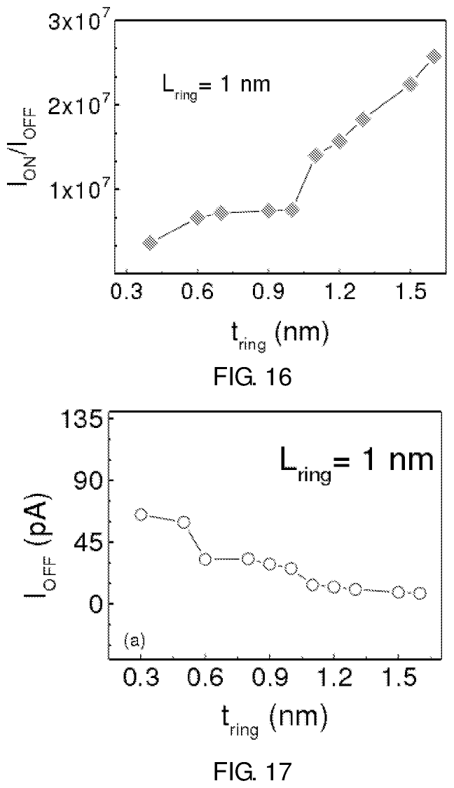

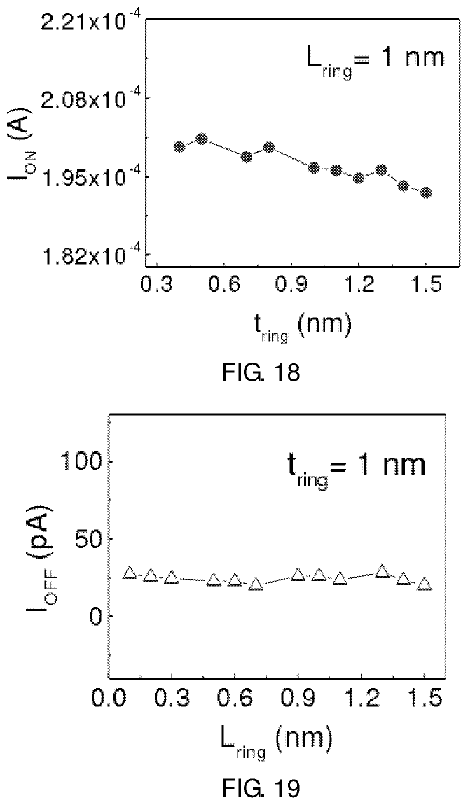

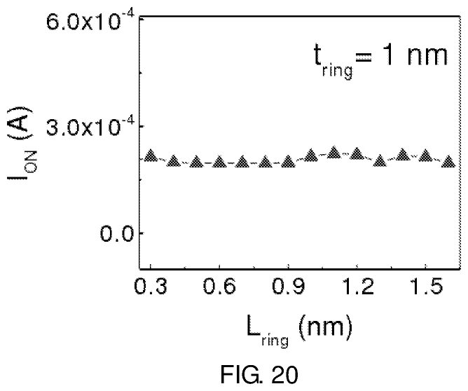

The influence of the thicknesses and lengths of the dielectric rings on the on-state current Iₒₙ, off-state leakage current I_{off} and on-off characteristics of the device is as shown in FIG. 16 to FIG. 20. The on-state current Iₒₙ of the device is a drain current of the device when the device is in a normal operating state; and the off-state leakage current I_{off} of the device is a drain current of the device when the device is in an off state. FIG. 16 is a chart of changing trend of an on-off ratio with thicknesses of dielectric rings (t_{ring}) according to one embodiment of the present disclosure. The on/off ratio (Iₒₙ/I_{off}) of the device increases gradually with the thicknesses of the dielectric rings. FIG. 17 is a chart of changing trend of an off-state current with thicknesses of dielectric rings according to one embodiment of the present disclosure. The off-state current I_{off} of the device decreases gradually with the increase of the thicknesses of the dielectric rings. FIG. 18 is a chart of changing trend of an on-state current with thicknesses of dielectric rings according to one embodiment of the present disclosure. The on-state current Iₒₙ of the device decreases gradually with the increase of the thicknesses of the dielectric rings. FIG. 19 is a chart of changing trend of an off-state ratio with lengths of dielectric rings (L_{ring}) according to one embodiment of the present disclosure. The off-state current I_{off} of the device remains basically unchanged with the increase of the thicknesses of the dielectric rings. FIG. 20 is a chart of changing trend of an on-state current with lengths of dielectric rings according to one embodiment of the present disclosure. The on-state current Iₒₙ of the device does not change much with the increase of the thicknesses of the dielectric rings, and also maintains around a stable value. It can be known from the above analysis that, as the thicknesses of the dielectric rings increase, the on-state current and off-state current of the device will gradually decrease. The main reason is that the increase of the dielectric rings will relatively reduce the cross-sectional area of the channels at the junctions with the drains. L-BTBT mainly occurs between the channels and the drains, namely positions where the two are connected. The reduction of the cross-sectional area will lead to a decrease in the total amount of tunneling. Therefore, the value of the off-state current will also change accordingly. As the value of the off-state current decreases, the total current flow decreases, which in turn leads to a decrease in the on-state current. In another aspect, the carriers that generate a GIDL current have an edge-clustering effect during transitions. That is, the transition ratio of nanowires close to the surfaces will increase significantly. In the present disclosure, the insulating dielectric ring layers are deposited at the peripheries of one ends of the channels close to one ends of the drain extension regions, thereby blocking the probability of carrier transition to a certain extent, reducing the influence of parasitic diode behaviors, and effectively reducing the L-BTBT current. Moreover, annular dielectrics in the channels and the gate oxide layer are made of the same material, which will not increase the influence of the fence parasitic capacitance on dynamic characteristics of the device. Therefore, on the premise of not influencing the dynamic characteristics of the device, adding the dielectric rings can effectively reduce the GIDL current, reduce the static power consumption, increase the on-off ratio of the device, and enhance the reliability of the device. It can be known from FIG. 16 to FIG. 18 that the increase in the thicknesses of the dielectric rings has a significant effect on suppressing the GIDL effect, and can improve the performance of the transistor and related semiconductor products.

To protect the gates 5 inside the transistor and other structures from being easily damaged, a passivation layer 7 is arranged on the gates 5; the passivation layer 7 is provided with one end fitted with the gates 5 and the other end flush with the tops of the silicon support pillars 1; the passivation layer 7 wraps one end of the gate oxide layer 4, the passivation layer 7 is arranged between adjacent two of the second isolation layers 6, and the passivation layer 7 between the plurality of silicon support pillars 1 in each column is connected. As shown in FIG. 1, the passivation layer 7 is located above the gates 5, and fills up regions in addition to the gate oxide layer 4 and the second isolation layers 6. The passivation layer 7 is made of a suitable material, such as oxides, nitrides, or combinations thereof. After the filling of the passivation layer 7 is completed, chemical mechanical polishing (CMP) needs to be performed on the surface of the transistor, which can make the surface of the transistor smooth and tidy.

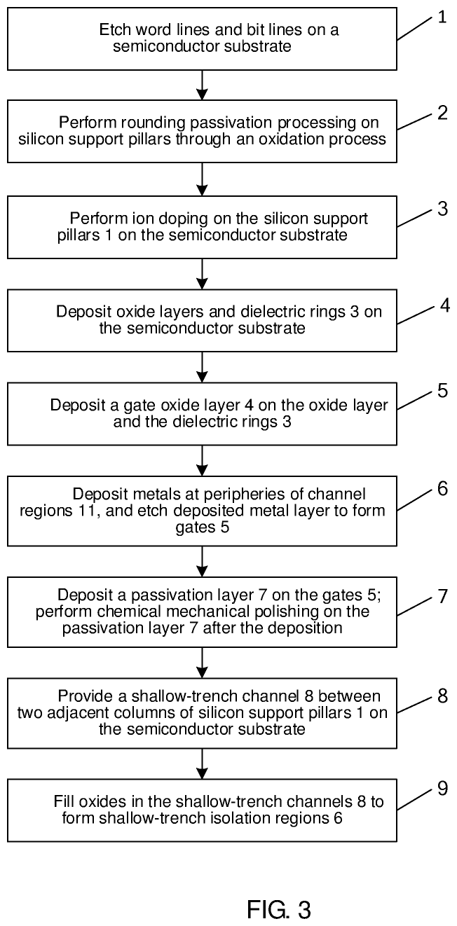

FIG. 3 is a flowchart of fabrication of a transistor according to one embodiment of the present disclosure. To enable the structure of the above transistor to be fabricated, the following steps need to be followed when fabricating the above transistor:

1. FIG. 4 is a schematic structural diagram of silicon support pillars of a transistor in an initial state according to one embodiment of the present disclosure. Word line trenches 9 and bit line trenches 13 are etched on the semiconductor substrate. When etching the word line trenches 9 and the bit line trenches 13, a photolithography process, such as a deep ultraviolet (DUV) process, an immersion photolithography process, a double patterning (DQP) process, a quadruple patterning (QPT) process, and/or an extreme ultraviolet (EUV) process may be used. After the etching, a layer of oxides is left at the top of the semiconductor substrate to protect the top of the semiconductor substrate from being silicided when the bit lines are silicided later. The oxide, metal and other layers deposited in the following fabrication steps are all deposited between the plurality of silicon support pillars 1 and filled in the word line trenches 9 and the bit line trenches 13. The purpose of etching the bit line trenches 13 is to form the bit lines 14 in the bit line trenches 13, the bit lines 14 are formed along the direction of the bit line trenches 13, and the bit lines 14 are located below the silicon support pillars 1. The bit lines 14 may be formed prior to the start of the following subsequent steps, and the bit lines 14 are embedded in the semiconductor substrate.

2. FIG. 5 is a schematic structural diagram of silicon support pillars of a transistor after rounding processing according to one embodiment of the present disclosure. The silicon support pillars are subjected to the rounding passivation processing through an oxidation process. The square or rectangular silicon support pillars 1 are changed into cylindrical or elliptical cylindrical silicon pillars, such that the sizes of the silicon support pillars 1 may be further reduced, and the existing process challenges may be reduced. Moreover, the oxide layers are etched after being fabricated by the thermal oxidation process. The purpose of rounding passivation is to form cylinders. Through the action of oxidation, more corners are oxidized and removed, thereby forming the cylinders.

3. FIG. 6 is a schematic structural diagram of silicon support pillars of a transistor during ion doping processing according to one embodiment of the present disclosure. Ion doping is performed on the silicon support pillars 1 on the semiconductor substrate; and after the doping, a channel region 11, a source region 12, and a drain region 10 are formed on each of the silicon support pillars 1 (as shown in FIG. 1). The silicon support pillars 1 are subjected to ion doping multiple times, and the ion doping concentration gradient on the silicon support pillars 1 decreases gradually from top to bottom. Setting the ion doping concentration gradient to relatively gentle Gaussian doping may effectively reduce the leakage of L-BTBT, thereby reducing I_{off} (off-state leakage current of the device). N⁺ represents high concentration, and N⁻ represents low concentration. A relatively gentle concentration gradient is achieved through more than three times of doping. The channels and the substrate all show uniform ion doping concentration distribution, the doping concentrations are all 1e17 cm⁻³, the Gaussian distribution doping mode is used in source/drain extension regions, the highest doping concentration is 1e20 cm⁻³, and the Gaussian doping gradient is 1.3 mm/decade.

It should be noted that the gentle ion doping concentration gradient may mainly extend transition regions between the channel regions and the drain regions. When the Gaussian doping gradient in the source/drain extension regions increases from 1.3 nm/decade to 3.3 nm/decade in strides of 0.3 nm/decade, both the on-state current (Iₒₙ) and the off-state current (I_{off}) show a monotonically decreasing trend. Therefore, the source/drain extension regions are set to relatively gentle Gaussian doping, which may effectively reduce the leakage of L-BTBT, thereby reducing the off-state current of the device. With the increase of the doping gradient in the source/drain extension regions, the parasitic resistance of the device will increase, and the on-state current will gradually decrease. When there is a relatively steep doping distribution such as 1.3 mm/decade, the peak electric field of the device at the interfaces between the drain extension regions and the channels increases significantly, while the fringing electric field at the same position decreases. The smaller the doping gradient, the smaller the L-BTBT tunneling width, the greater the tunneling probability, and the greater the off-state current. Therefore, using a relatively gentle Gaussian doping distribution in the source/drain extension regions of the gate-around device can effectively suppress L-BTBT, thereby achieving the effect of reducing the off-state current.

4. The oxide layers and the dielectric rings 3 are deposited on the semiconductor substrate; and each of the dielectric rings 3 wraps one of the silicon support pillars 1. Step 4 includes:

4-1. FIG. 7 is a schematic structural diagram of a transistor after deposition of dielectric rings in this embodiment. A first oxide layer 21 is deposited on the semiconductor substrate, and the first oxide layer 21 is etched after the deposition; and the dielectric rings 3 are deposited on the first oxide layer 21. In this step, the dielectric rings 3 are continuous dielectric rings, and the heights of the dielectric rings 3 only need to be greater than the heights required by the first dielectric rings 31 and do not necessarily have to reach the tops of the silicon support pillars 1.

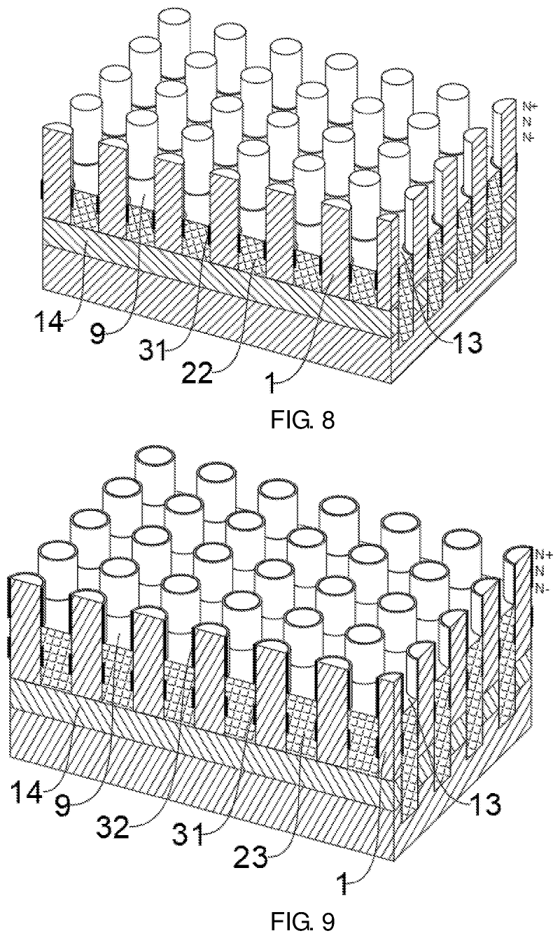

4-2. FIG. 8 is a schematic structural diagram of a transistor after deposition of a second oxide layer in this embodiment. The dielectric rings 3 are etched after the deposition, and dielectric ring segments are retained by a specified height as the first dielectric rings 31; the oxide layer is continuously deposited on the first oxide layer 21 to form a second oxide layer 22; and the second oxide layer 22 and the first dielectric rings 31 are etched, such that tops of the second oxide layers 22 are flush with tops of the first dielectric rings 31.

4-3. FIG. 9 is a schematic structural diagram of a transistor after deposition of second dielectric rings in this embodiment. The oxide layer is continuously deposited on the second oxide layer 22 (as shown in FIG. 8) to form a third oxide layer 23, and the third oxide layer 23 is etched; and the second dielectric rings 32 are deposited on the third oxide layer 23, and the second dielectric rings 32 are etched. At this time, the tops of the second dielectric rings 32 are flush with the tops of the silicon support pillars 1. In addition, it should be noted that, at this time, the deposition of the oxide layers is performed successively to form separations between the first dielectric rings 31 and the second dielectric rings 32, and a base for supporting the second dielectric rings 32 is constructed below the second dielectric rings 32, which facilitates the deposition of the second dielectric rings 32.

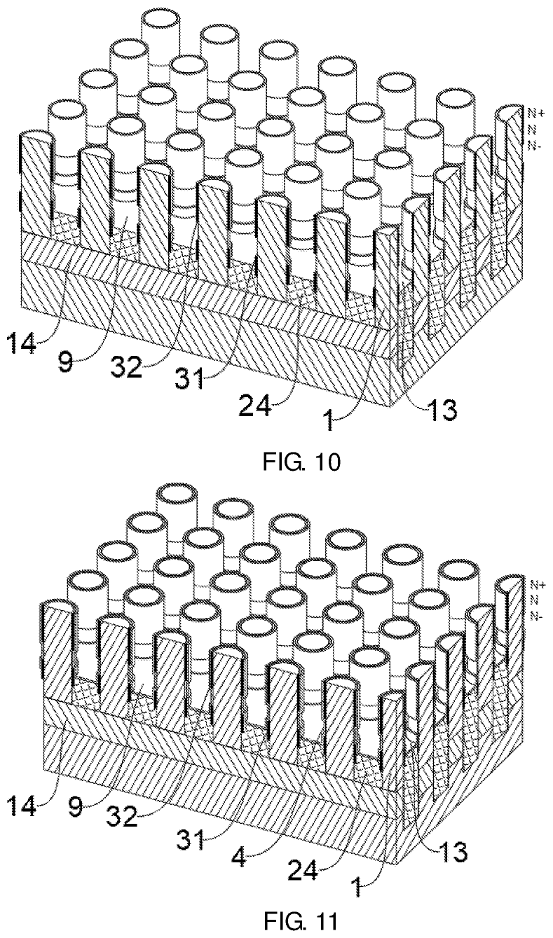

4-4. FIG. 10 is a schematic structural diagram of a transistor after etching of third oxide layers in this embodiment. The third oxide layer 23 (as shown in FIG. 9) is etched to form a fourth oxide layer 24, and a top of the fourth oxide layer 24 is lower than the tops of the first dielectric rings 31.

5. FIG. 11 is a schematic structural diagram of a transistor after deposition of the gate oxide layer according to one embodiment of the present disclosure. A gate oxide layer 4 is deposited on the fourth oxide layer 24; and the gate oxide layer 4 wraps the first dielectric rings 31 and the second dielectric rings 32. Specifically, atomic layer deposition is performed on the fourth oxide layer 24 to form the gate oxide layer 4, and the gate oxide layer 4 is fitted with an upper surface of the fourth oxide layer 24, an outer surface of each of the first dielectric rings 31, an outer surface of each of the second dielectric rings 32, and an outer surface of each of the silicon support pillars between the first dielectric ring 31 and the second dielectric ring 32. The atomic layer deposition (ALD) is performed on the basis of the structure shown in FIG. 10 to form the oxide layer as the gate oxide (GOX) layer 4.

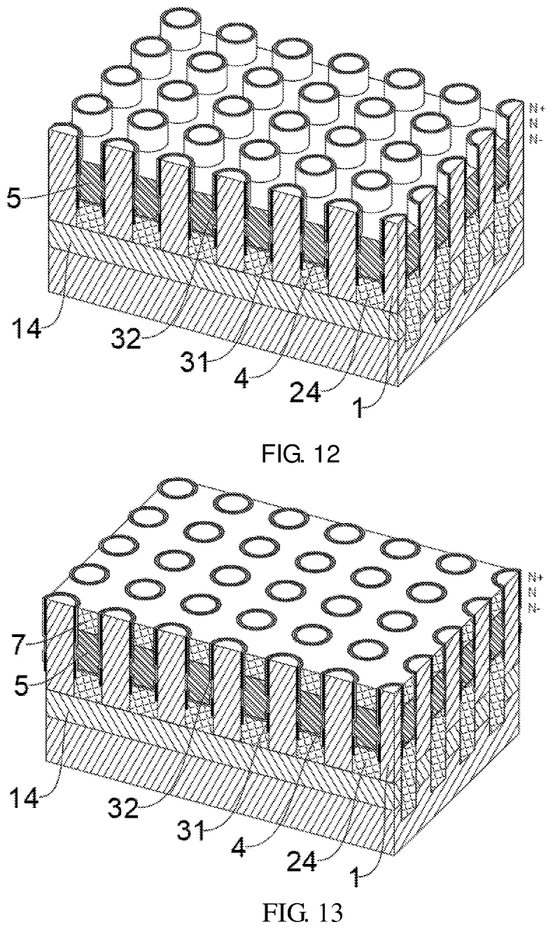

6. FIG. 12 is a schematic structural diagram of a transistor after deposition of gates according to one embodiment of the present disclosure. Metals are deposited at the peripheries of the channel regions 11, and the deposited metal layer is etched to form the gates 5 as the word lines in the transistor. The side surface of each of the gates 5 close to the silicon support pillar 1 is the first surface 51, and the side surface of each of the gates 5 distant from the silicon support pillar 1 is the second surface 52 (as shown in FIG. 2). The length of the first surface 51 of each of the gates 5 is less than the length of the channel region 11 of each of the silicon support pillars, and both ends of each of the channel regions 11 extend from both ends of the first surface 51 of each of the gates 5. specifically, the gates 5 are deposited on the gate oxide layer 4; and the gates 5 are lower than the tops of the second dielectric rings 32. To facilitate the deposition of the metals of the gates 5 and to control the internal units of the transistor later, when the gates 5 are deposited, the gates 5 around the plurality of silicon support pillars 1 are connected to one another. That is to say, the metal layer of the gates 5 are arranged in all gaps between the silicon support pillars 1. During actual operation of the transistor, the effective height of the first dielectric rings 31 and the effective height of the second dielectric rings 32 are parts surrounded by the gates 5. The height range of the first dielectric rings 31 and the height range of the second dielectric rings 32 are preferably 0.3-3 nm.

7. FIG. 13 is a schematic structural diagram of a transistor after deposition of a passivation layer according to one embodiment of the present disclosure. The passivation layer 7 is deposited on the gates; and the passivation layer 7 is made of oxides, nitrides, or combinations thereof. After the deposition, the chemical mechanical polishing is performed on the passivation layer 7 to ensure the smoothness of the surface of the transistor.

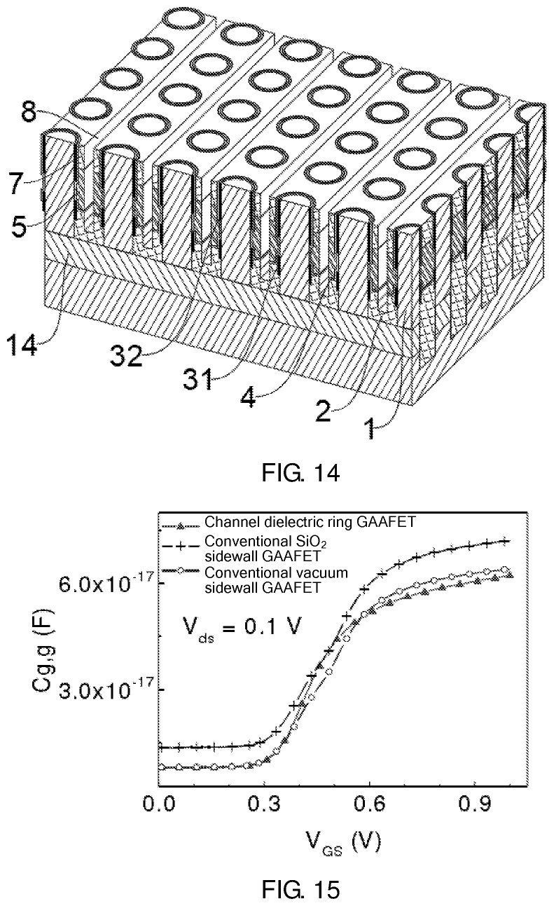

8. A shallow-trench channel 8 is provided between two adjacent columns of silicon support pillars 1 on the semiconductor substrate; and the shallow-trench channels 8 are located on the first isolation layer 2. FIG. 14 is a schematic structural diagram of a transistor after etching of shallow-trench channels according to one embodiment of the present disclosure. The depths of the shallow-trench channels 8 reach the insides of the first oxide layer 21 (as shown in FIG. 7) on the semiconductor substrate to form the first isolation layer 2.

9. The shallow-trench channels 8 are filled with oxides to form the second isolation layers 6, thereby finally forming the transistor structure as shown in FIG. 1.

In addition, it should be noted that those skilled in the art can change the above sequence without departing from the protection scope of the present disclosure. For example, steps 8 and 9 may be performed after step 5. That is, firstly, the second isolation layers 6 of the word lines are constructed, and then the metals are deposited to form the gates 5 as the word lines.

According to the above transistor, by adjusting the lengths of the gates and the ion doping concentration gradient in the source/drain regions, the length of partial overlap between the gates and the channel regions is increased, the ion doping concentration gradient in the source/drain regions shows a gentle distribution, and the width of band-to-band tunneling is increased, thereby effectively improving the band-to-band tunneling between the channels and the gates, alleviating the off-state leakage caused by L-BTBT, and reducing the GIDL effect of the device.

In addition, the insulating dielectrics (i.e., dielectric rings) are added at the peripheries of channels close to the drain extension regions, and may be made of insulating materials such as silicon dioxide, silicon nitride, and hafnium dioxide, which can effectively reduce the probability of band-to-band tunneling, thereby reducing the off-state current.

A memory can be fabricated by using the above transistor, and the original transistor in the memory can be replaced with the above transistor. The memory includes the above transistor, which can reduce the GIDL effect, reduce the probability of band-to-band tunneling, and prolong the service life of the memory.

Although the present disclosure is described in detail with reference to the foregoing embodiments, those of ordinary skill in the art should understand that they can still modify the technical solutions described in the foregoing embodiments, or make equivalent substitutions on some technical features therein. These modifications or substitutions do not make the essence of the corresponding technical solutions deviate from the spirit and scope of the technical solutions of the embodiments of the present disclosure.

1. A transistor, comprising:
a semiconductor substrate; silicon support pillars, located on the semiconductor substrate; and gates, each of the gates arranged around one of the silicon support pillars; wherein,
a side surface of each of the gates close to the silicon support pillar is a first surface, a side surface of each of the gates distant from the silicon support pillar is a second surface, and a length of the first surface is less than a length of the second surface; and the length of the first surface of each of the gates is less than a length of a channel region of each of the silicon support pillars.

2. The transistor according to claim 1, wherein ion doping is performed on an upper end of each of the silicon support pillars to form a drain region, the channel region, and a source region, the drain region is connected to one end of the channel region, and the other end of the channel region is connected to the source region.

3. The transistor according to claim 1, wherein the silicon support pillars are subjected to ion doping multiple times, and an ion doping concentration gradient on the silicon support pillars shows a Gaussian doping distribution and decreases gradually from top to bottom.

4. The transistor according to claim 1, wherein the silicon support pillars are uniformly distributed on the semiconductor substrate, and the silicon support pillars are silicon support pillars after rounding passivation.

5. The transistor according to claim 1, wherein the semiconductor substrate is covered with a first isolation layer, second isolation layers are provided on the first isolation layer, one end of each of the second isolation layers is inserted into the first isolation layer, and each of the second isolation layers is located between two adjacent columns of the silicon support pillars.

6. The transistor according to claim 5, wherein each of the silicon support pillars is coated with a dielectric ring;
each of the dielectric rings comprises a first dielectric ring and a second dielectric ring, each of the first dielectric rings is provided with one end inserted into the first isolation layer and the other end close to the gate, and each of the second dielectric rings is provided with one end close to the gate and the other end located on a same horizontal plane with a top of the silicon support pillar.

7. The transistor according to claim 6, wherein a protrusion is provided on one side of each of the gates close to an outer surface of the silicon support pillar, and the protrusion is located between the first dielectric ring and the second dielectric ring.

8. The transistor according to claim 6, wherein a gate oxide layer is provided between the first dielectric ring and the gate, between the second dielectric ring and the gate, and between the silicon support pillar and the gate; and the gate oxide layer is provided with one end fitted with the first isolation layer and the other end flush with the tops of the silicon support pillars.

9. The transistor according to claim 8, wherein a passivation layer is arranged on the gates; the passivation layer is provided with one end fitted with the gates and the other end flush with the tops of the silicon support pillars; the passivation layer wraps one end of the gate oxide layer, the passivation layer is arranged between adjacent two of the second isolation layers, and the passivation layer between a plurality of silicon support pillars in each column is connected.

10. A method of fabricating a transistor, comprising:
performing ion doping on silicon support pillars on a semiconductor substrate; and forming a channel region, a source region, and a drain region on each of the silicon support pillars after the doping; and
depositing a gate at a periphery of each of the channel regions; wherein, a side surface of each of the gates close to the silicon support pillar is a first surface, a side surface of each of the gates distant from the silicon support pillar is a second surface, and a length of the first surface is less than a length of the second surface; and the length of the first surface of each of the gates is less than a length of the channel region of each of the silicon support pillars.

11. The method of fabricating a transistor according to claim 10, wherein the silicon support pillars are subjected to ion doping multiple times, and an ion doping concentration gradient on the silicon support pillars shows a Gaussian doping distribution and decreases gradually from top to bottom.

12. The method of fabricating a transistor according to claim 10, before depositing a gate at a periphery of each of the channel regions, further comprises:
depositing oxide layers and dielectric rings on the semiconductor substrate, each of the dielectric rings wrapping one of the silicon support pillars; and
depositing a gate oxide layer on the oxide layer and the dielectric rings on the semiconductor substrate, the gate oxide layer wrapping the dielectric rings.

13. The method of fabricating a transistor according to claim 12, wherein the depositing oxide layers and dielectric rings on the semiconductor substrate comprises:
depositing a first oxide layer on the semiconductor substrate, and etching the first oxide layer after the deposition;
depositing dielectric rings on the first oxide layer;
etching the dielectric rings after the deposition, and retaining dielectric ring segments by a specified height as first dielectric rings;
continuously depositing an oxide layer on the first oxide layer to form a second oxide layer;
etching the second oxide layer and the first dielectric rings, such that a top of the second oxide layer is flush with tops of the first dielectric rings;
continuously depositing an oxide layer on the second oxide layer to form a third oxide layer, and etching the third oxide layer;
depositing second dielectric rings on the third oxide layer, and etching the second dielectric rings; and
etching the third oxide layer to form a fourth oxide layer, a top of the fourth oxide layer being lower than the tops of the first dielectric rings.

14. The method of fabricating a transistor according to claim 13, wherein the depositing a gate oxide layer on the oxide layer and the dielectric rings comprises:
performing atomic layer deposition on the fourth oxide layer to form a gate oxide layer, the gate oxide layer being fitted with an upper surface of the fourth oxide layer, an outer surface of each of the first dielectric rings, an outer surface of each of the second dielectric rings, and an outer surface of each of the silicon support pillars between the first dielectric ring and the second dielectric ring.

15. The method of fabricating a transistor according to claim 13, wherein the depositing a gate at a periphery of each of the channel regions comprises:
depositing gates on the gate oxide layer; wherein,
the gates are lower than tops of the second dielectric rings; a side surface of each of the gates close to the silicon support pillar is a first surface, and a side surface of each of the gates distant from the silicon support pillar is a second surface; and the length of the first surface of each of the gates is less than the length of the channel region of each of the silicon support pillars.

16. The method of fabricating a transistor according to claim 10, after depositing a gate at a periphery of each of the channel regions, further comprises:
depositing a passivation layer on the gates, the passivation layer being made of oxides or nitrides; and
performing chemical mechanical polishing on the passivation layer.

17. The method of fabricating a transistor according to claim 12, after depositing a gate oxide layer on the oxide layer and the dielectric rings or after depositing a gate at a periphery of each of the channel regions, further comprises:
providing a shallow-trench channel between two adjacent columns of the silicon support pillars on the semiconductor substrate, the shallow-trench channels being located on a first isolation layer.

18. The method of fabricating a transistor according to claim 17, wherein the shallow-trench channels are filled with oxides to form second isolation layers.

19. The method of fabricating a transistor according to claim 10, further comprising:
performing rounding passivation processing on the silicon support pillars through an oxidation process before the ion doping is performed on the silicon support pillars on the semiconductor substrate.

20. A memory, comprising the transistor according to claim 1.
